(19) United States
(12) Patent Application Publication
(10) Pub. No.: US 2003/0179842 A1
(43) Pub. Date: Sep. 25, 2003

(54) Digital pattern sequence generator

(76) Inventors: Michael G. Kane, Skillman, NJ (US); Thomas Senko, Plainsboro, NJ (US)

Correspondence Address: Steve Mendelsohn, Mendelsohn & Associates, P.C., Suite 715, 1515 Market Street, Philadelphia, PA, 19102, US

(21) Appl. No.: 10/383,474

(22) Filed: Mar. 7, 2003

Related U.S. Application Data
(60) Provisional application No. 60/366,982, filed on Mar. 22, 2002.

(51) Int. Cl. H03D 3/24

(52) U.S. Cl. 375/376

(57) ABSTRACT

A pattern generator employs a delay-locked loop (DLL) to generate a control signal for locking a delay though each element in a reference generator string to a reference signal. The control signal is also employed to lock a delay though each element in a pattern generator string to the reference signal. The elements may be slew-rate-controlled inverters, where the DLL control signal adjusts the slewing-rate of the inverter. Given a signal applied to the pattern generator string, combination logic assembles one or more pulses from the two or more signals selected from the input and output taps of each of the series of elements in the pattern generator string. Since the delay through each element of the series of elements in the pattern generator string is locked, the period of each pulse may exhibit relatively accurate timing with respect to the reference.

### CROSS-REFERENCE TO RELATED APPLICATIONS

This application claims the benefit of the filing date of U.S. provisional application No. 60/366,982, filed on Mar. 22, 2002 as attorney docket no. SAR 14474P.

### BACKGROUND OF THE INVENTION

1. Field of the Invention

The present invention relates to circuits for generating digital patterns, and, in particular, to generating digital patterns using a delay-locked loop or a phase-locked loop.

2. Description of the Related Art

A common method for generating a sine wave or square wave with relatively high accuracy in frequency employs a phase-locked loop (PLL). A PLL is a circuit that generates, or synthesizes, a periodic output signal that has a constant phase and frequency Fₒᵤₜ with respect to the phase and frequency Fᵢₙ of a periodic input signal. Usually, the frequency Fₒᵤₜ of the output signal is much higher than the frequency Fᵢₙ of the input signal. One type of PLL commonly used is the charge-pump PLL, which is described in Floyd M. Gardner, “Charge-Pump Phase-Locked Loops,” IEEE Trans. Commun., vol. COM-28, pp. 1849-1858, November 1980, the teachings of which are incorporated herein by reference.

The PLL generally comprises a phase detector, voltage-controlled oscillator (VCO), and a loop-filter, along with other components depending upon the type of PLL. A VCO is a device that generates a periodic output signal whose frequency is a function of the VCO input voltage. The input reference signal at frequency Fᵢₙ applied to the PLL might be a sine wave or square wave of some fixed, well-controlled frequency. The reference signal is applied to the phase detector, which also receives a signal based on the output of the VCO. The phase detector compares the phases (frequencies Fₒᵤₜ (from the VCO) and Fᵢₙ) of these two signals. Typically, the frequency of the VCO output signal and/or the frequency of the reference input signal is divided down by a fixed or programmable integer divisor before the comparison since the reference signal may be at a different frequency than the frequency of the output signal of the VCO. Based on the phase comparison of the two signals, the phase detector generates an error signal that may be employed to steer the output signal of the VCO up or down in frequency. The error signal is generally a pulse, and the width of the pulse is related to the amount of error while the sign of the pulse indicates whether the error is positive or negative.

If a charge pump is employed, the charge-pump generates an amount of charge equivalent to the width of the error signal, and the sign of the charge indicates whether the frequency should be steered up or down. The charge from the charge-pump is then integrated by the loop filter, and the output voltage V_{lf} the loop filter is employed as the input voltage to the VCO. Hence, loop filter voltage V_{lf} controls the frequency Fₒᵤₜ of the VCO output signal. A ring oscillator is commonly employed for a VCO when generating digital sequences, especially in fractional PLL implementations in which Fₒᵤₜ is a non-integer multiple of Fᵢₙ. A ring oscillator comprises a series of inverting stages (inverting amplifiers), with each inverting stage operating at a frequency and phase determined by i) the delay through each inverting stage and ii) the number of inverting stages in the ring oscillator. When the PLL is in-lock, the output of the VCO is at the desired frequency, and its frequency is as accurate as that of the reference input. Thus, the frequency of one or more outputs of the inverters in the ring oscillator may be locked to the frequency of a single input reference signal.

Such a PLL configuration is generally employed to generate sine waves or square waves, but might not give adequate performance for generating relatively short digital patterns. For example, a very simple pattern might be a single pulse that has an accurate pulse width with respect to an input signal. More complex patterns might consist of a series of several pulses. While it is straightforward to generate an arbitrary series of pulses using digital logic, generation of sequences of pulses having high timing accuracy when compared to a reference is more complex.

For example, a single pulse with a well-controlled pulse width might be generated in response to a rising edge on an input trigger. To prevent the pulse width from depending on the highly variable delays through logic gates, a PLL produces a square wave locked to a reference frequency, with half the period of the square wave equal to the desired pulse width. These variable delays usually depend on processing, operating temperature, and related characteristics of the semiconductor implementation. Then, in response to the trigger, a single half-cycle of the square wave is selected from the repeating series of pulses that the square wave contains. However, if the trigger input is asynchronous with respect to the reference input, a “glitch” rather than a pulse might be generated at the output. Such glitch might be generated when the occurrence of the trigger falls within certain time intervals relative to the timing of the reference input. Second, a single pulse might not be derived from the square wave if the desired single pulse is shorter in width than the width (in time) of a few logic-gate delay periods. Since a flip-flop (or a similar circuit used as the logic gate) is toggled on and off to let a single pulse pass, this toggling requires a duration of a few gate delay periods to accomplish. In view of these disadvantages of generating a single pulse from a square wave, an alternative method might be generation of a limited series of pulses at the outset. However, timing of the series of pulses should be locked to a reference signal in order to ensure that the sequence of pulses is generated accurately with respect to a desired point of time.

A circuit similar to a PLL is a delay-locked loop (DLL), which generally comprises a phase detector, voltage-controlled delay line (VCDL), and a loop-filter, along with other components depending upon the type of DLL. A DLL is generally employed to generate an output signal having a known delay with respect to an input signal. A VCDL is a device that generates delayed version of an input signal whose delay is a function of the VCDL input voltage. A VCDL is generally implemented as a series of voltage controlled delay elements, such as an inverter string. The phase detector and loop filter are employed to measure a delay error and generate a feedback signal for the VCDL to drive the delay error to zero.

Further aspects and advantages of this invention will become apparent from the detailed description, which follows.

### SUMMARY OF THE INVENTION

The problems in the prior art are addressed in accordance with the principles of the present invention by generating a limited-length sequence of pulses, wherein the timing of the series of pulses is in a locked state with respect to a reference signal. The present invention is directed to a pattern generator in which a delay-locked loop is employed to generate a control signal for locking a delay through each of a series of elements in a reference generator string to the reference signal. The control signal is also employed to lock a delay through each of a series of elements in a pattern generator string to the reference signal. In response to a signal applied to the pattern generator string, combination logic assembles one or more pulses from the two or more signals selected from the input and output taps of each of the series of elements in the pattern generator string. Since the delay through each element of the series of elements in the pattern generator string is locked to the reference, the period of each pulse may exhibit relatively accurate timing with respect to the reference.

According to one embodiment, the present invention generates a limited pulse sequence with a delay-locked loop (DLL), a pattern generator string, and a combiner. The DLL generates a control signal using a reference signal, the control signal employed by the DLL to adjust the delay of the reference signal passing through the DLL to a predetermined value when the DLL is in a locked state. The pattern generator string has at least one delay element and two or more taps, wherein a signal input to and a signal output from a delay element of the pattern generator string appears at a corresponding tap and wherein the delay of a signal passing through a delay element of the pattern generator string is based on the control signal applied to the delay element. The combiner combines two or more tap signals present at corresponding taps to form the pulse sequence, the two or more tap signals being present when a trigger signal is applied to the pattern generator.

### BRIEF DESCRIPTION OF THE DRAWINGS

Other aspects, features, and advantages of the present invention will become more fully apparent from the following detailed description, the appended claims, and the accompanying drawings in which like reference numerals identify similar or identical elements.

FIG. 1 shows a pattern generator operating in accordance with an exemplary embodiment of the present invention;

FIG. 2 shows an exemplary implementation for the combination logic of the pattern generator shown in FIG. 1;

FIG. 3 shows an exemplary implementation for the voltage controlled inverters shown in FIG. 1; and

FIG. 4 shows an exemplary implementation for the phase-locked loop shown in FIG. 1.

### DETAILED DESCRIPTION

In accordance with exemplary embodiments of the present invention, a pattern generator comprises a delay-locked loop (DLL) that provides a control signal that is employed to control delay through elements of a pattern generator string. A signal passing through the pattern generator string might appear at taps of the pattern generator string with a corresponding delay and phase shift. Two or more signals appearing at the taps might be combined to form an output, limited-length, sequence of pulses. A pattern sequence generator operating in accordance with exemplary embodiments of the present invention may provide one or more of the following advantages. First, exemplary embodiments of the present invention may provide for a limited sequence of pulses in which the timing of the pulses is locked to a reference signal. Second, exemplary embodiments of the present invention may provide a limited sequence of pulses having a relatively narrow pulse width. Third, exemplary embodiments of the present invention may provide a limited sequence of pulses having a relatively accurate pulse width. Fourth, exemplary embodiments of the present invention may provided a limited sequence of pulses forming a predefined pattern of pulses and missing pulses.

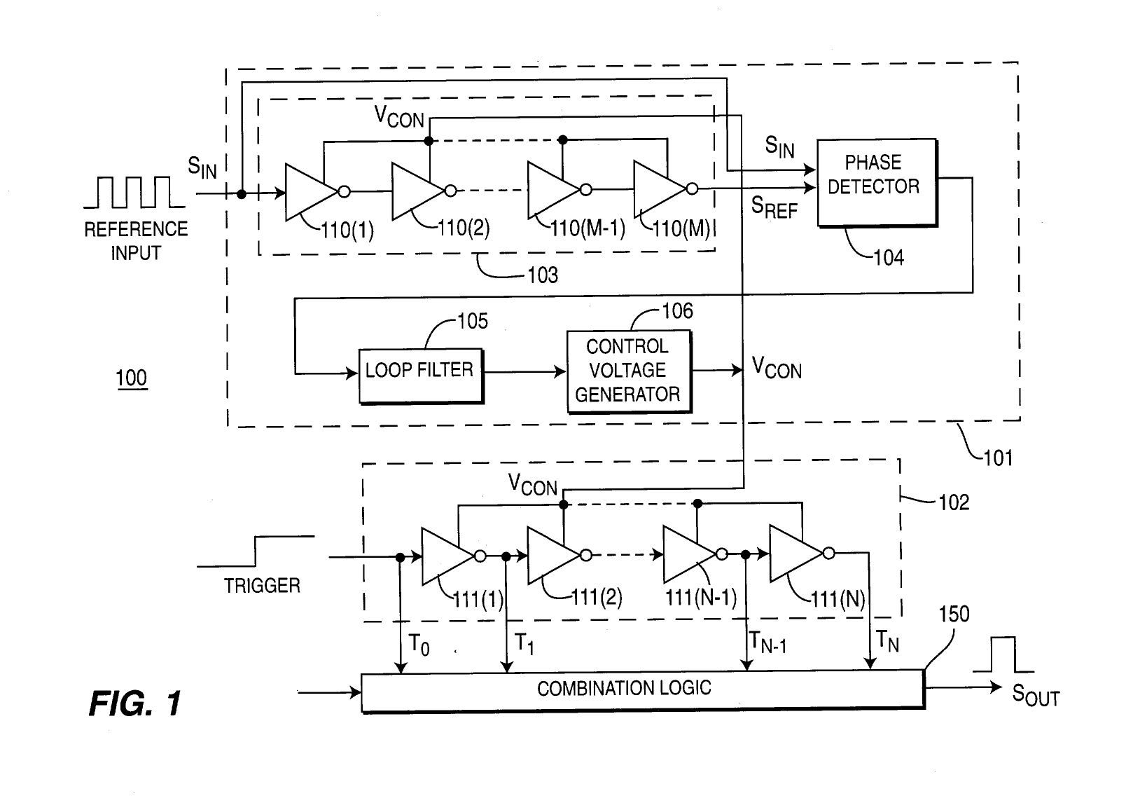

FIG. 1 shows a pattern generator 100 employing a DLL 101, pattern generator string 102, and combination logic 150 operating in accordance with an exemplary embodiment of the present invention. DLL 101 comprises a reference generator string 103 having a coupled string of M inverters 110(1)-110(M) (where M is a positive integer), a phase detector 104, a loop filter 105, and a control voltage generator 106. Together, phase detector 104, loop filter 105, and control voltage generator 106 form a control signal generator for DLL 101, and reference generator string 103 functions as a voltage controlled delay with one or more voltage controlled delay elements (e.g., each delay element may correspond to an inverter). Pattern generator string 102 comprises a coupled string of N inverters 111(1)-111(N) (where N is a positive integer).

DLL 101 receives as its input a reference signal S_{IN} at a given frequency. The reference signal S_{IN} might be a periodic signal, such as a sine wave or square wave, of fixed frequency f(shown as a square wave in FIG. 1). The reference signal S_{IN} is applied to the first inverter of reference generator string 103. For the described exemplary embodiment, each inverter of reference generator string 103 and pattern generator string 102 is a voltage-controlled inverter whose delay through the inverter might be adjusted with a control voltage V_{CON}. Control voltage V_{CON} might comprise one or more DC voltage signals. The reference signal S_{IN} is toggled through each of the M inverters 110(1)-110(M) to appear as the output signal of the last inverter 110(M). If M is even, reference generator string 103 employs an even number of inverters and the output of the last inverter 110(M) will correspond to the reference signal S_{IN}, but delayed by a period equal to the propagation delay through the M inverters. If M is odd, the output of the last inverter 110(M) will correspond to the reference signal S_{IN} shifted, in phase, by 180 degrees, but also delayed by a period equal to the propagation delay through the M inverters.

Phase detector 104 receives i) the reference signal S_{IN} and ii) the output S_{REF} of inverter 110(M) of reference generator string 103. Phase detector 104 compares the phase of the output of inverter 110(M) to the phase of the reference signal S_{IN} to generate a phase difference, or error, eₚ. The phase difference eₚ depends on the total delay through the inverters, if M is even (if M is odd, the 180-degree phase shift may be accounted for separately). The phase difference eₚ is applied to loop filter 105, which might be implemented with a low-pass filter, and loop filter 105 generates a DC voltage level related to the phase difference eₚ. The voltage level generated by loop filter 105 is applied to control voltage generator 106. Based on the received DC voltage level, control voltage generator 106 produces the control voltage V_{CON} fed back to reference generator string 103. Each of the inverters 110(1)-110(M) employs the control voltage V_{CON} to adjust the signal propagation delay through the inverter. When DLL 101 is in a locked state, the delay through each inverter has a value that is locked to the period (and, hence, the frequency) of the reference signal S_{IN}.

For example, a logic gate, such as an exclusive-or (XOR) gate, may be employed as phase detector 104. Such an XOR gate exhibits a 50% duty cycle, corresponding to equal high and low signal periods, when there is a 90-degree phase shift between the two signals applied to the XOR gate. If this 50% duty cycle occurs during the locked state for DLL 101, a 90-degree phase shift corresponds to a time delay of one quarter of the period T (T=l/f) of the reference signal S_{IN}. Thus, when the DLL is in the locked state, each inverter in a string of M inverters has a delay of exactly T/4M.

DLL 101 of FIG. 1 is shown having the reference signal S_{IN} and the output S_{REF} as equivalent but delayed signals. One skilled in the art would realize that other configurations may be possible for DLL 101 of FIG. 1. In addition, the circuit of FIG. 1 corresponding to the DLL may be a portion of a phase-locked loop (PLL) in which reference inverter string 103 acts as a voltage controlled delay, but is included within a ring oscillator. Such ring oscillator might be configured as reference inverter string 103 with M an odd number, the output S_{REF} applied to its input as the reference signal S_{IN}, and a phase detector employed to maintain the frequency of the ring oscillator's reference signal S_{IN} with respect to an external timing signal. For such an embodiment, maintaining the frequency of the output of the ring oscillator might generate a control voltage for the delay elements (inverters) of the reference inverter string that may be subsequently employed by a pattern generator string to set the delay through each element of the pattern generator string.

Pattern generator string 102 might employ a similar string of inverters as employed by reference generator string 103 which are controlled via control voltage V_{CON}. Consequently, pattern generator string 102 is in a locked state similar to the locked state of reference generator string 103 with respect to the input reference signal S_{IN}. Thus, each of the inverters in pattern generator string 102 has substantially the same delay as the inverters of reference generator string 103. Pattern generator string 102 receives, for example, a trigger signal (shown as a rising-edge trigger in FIG. 1) to generate a pattern. The trigger signal is applied to inverter 111(1) of pattern generator string 102. The input signal to each of N inverters 111(1) through 111(N) and the output of inverter 111(N) are available to combination logic 150 at corresponding taps T₀ through T_{N}. One skilled in the art would realize that, instead of a rising-edge trigger signal, the signal applied to pattern generator string 102 might be of a different form. The signal applied to pattern generator string 102 might be, for example, a square wave of period much greater than the period of the reference signal, or a signal having a predetermined sequence of rising and falling edges.

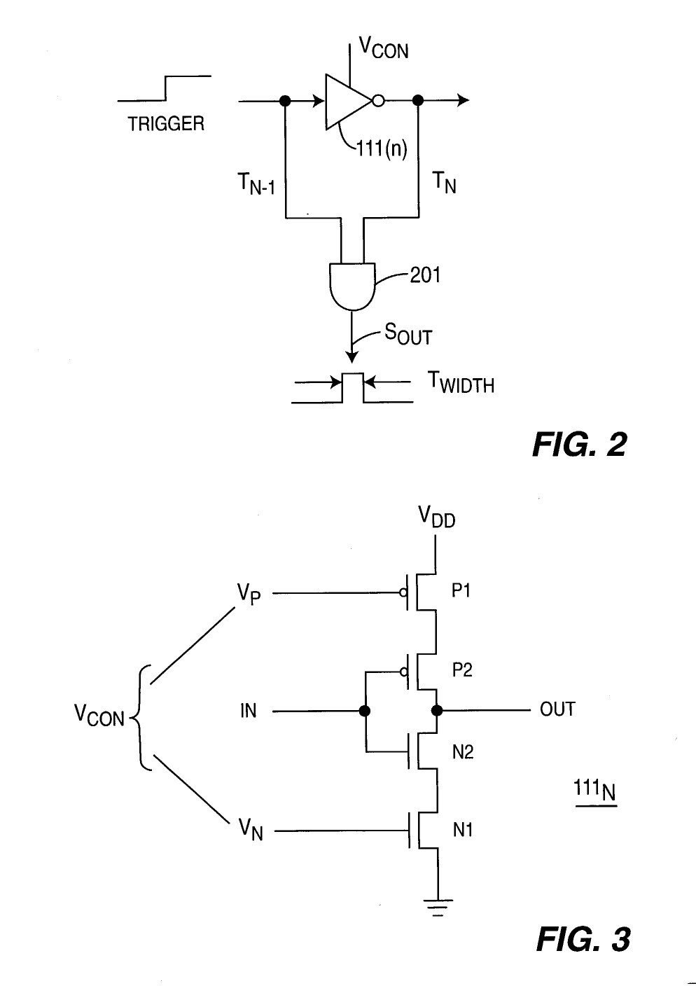

Combination logic 150 is a signal combiner comprising, for example, one or more logic gates combining two or more output signals present at taps T₀ through T_{N} to form a digital pattern. Operation of combination logic 150 is now described for the example of forming a single pulse locked to an input trigger signal (which might also be synchronized to the reference signal S_{IN}), where the input trigger signal comprises a rising edge transition. For example, as shown in FIG. 2, AND gate 201 might employed to construct the single pulse from the rising-edge trigger signal at any one of the taps (e.g., Tₙ₋₁) and a falling edge at the following tap (e.g., Tₙ) of inverter 111(n).

AND gate 201 receives both the input signal of inverter 111(n) at tap Tₙ₋₁ and the output signal of inverter 111(n) at tap Tₙ. Initially, the output of inverter 111(n) at tap Tₙ is high, since the input to inverter 111(n) is low, causing AND gate 201 to generate a logic low until receiving the rising edge of the trigger signal. Once the rising edge of the trigger signal is input to inverter 111(n), the signal at tap Tₙ is logic high. The period of delay through inverter 111(n) causes AND gate 201 to see both a logic high from tap Tₙ₋₁ and a logic high at tap Tₙ since it takes an inverter delay period for the output of inverter 111(n) to change logic states. For this inverter delay period, the output of AND gate 201 is logic high. The output of AND gate 201 goes low once the output of inverter 111(n) changes state, causing AND gate 201 to generate the pulse having a pulse width equivalent to one inverter delay period. If pattern generator string 102 is in a locked state with respect to the reference signal S_{IN}, the delay of inverter 111(n) is also locked to the reference signal S_{IN}, allowing for a pulse to be generated with a well-controlled pulse width t_{width}. For example, if the reference signal S_{IN} has a frequency f=25 MHz (period T=40 nsec) and the reference generator string comprises M=N=100 inverters, then t_{width} is T/4N=100 psec when the system is a locked state.

If a single pulse is generated by using the taps at T₀ and T₁, the resulting pulse will occur when the trigger signal is applied to pattern generator string 102. If a delay is desired between applying the trigger signal and generation of the pulse, a delay by one or more inverter delay periods may be inserted by selecting taps of inverters further in the pattern generator string. For example, selecting taps T₂ and T₃ corresponding to inverter 111(3) generates a single pulse delayed by two inverter delay periods from the application of the trigger signal.

The example of FIG. 2 may be extended to form a pulse having a width greater than one inverter delay period. For this case, AND gate 201 constructs a pulse from a rising edge at any one of the taps (e.g., T₀) and a falling edge at any one of the subsequent taps (e.g., Tₙ, where n is odd). Consequently, to form a pulse having a pulse width of three inverter delay periods, the taps selected would be Tₙ and Tₙ₊₃, where n is 0≦n≦N−2.

In addition, the example of FIG. 2 employs an odd number of inverters because the AND gate requires a rising-edge signal and a falling-edge signal to construct the pulse. Consequently, the AND gate of FIG. 2 generates a pulse having a width of an odd number of inverter delay periods. However, one skilled in the art would realize that the signal at any given tap may be complemented, allowing for a pulse constructed with a width equivalent to an even number of inverter delay periods. If logic gates having complementary outputs are used, then no additional, untracked delay is added.

The example of FIG. 2 may be extended to form two pulses displaced in time by a specified number of inverter delay periods. For example, two AND gates and an OR gate may be employed to generate a sequence of two pulses from an input rising-edge trigger signal. The first AND gate may receive the signals from taps T₀ and T₁, while the second AND gate may receive the signals from taps T₄ and T₅. The first and second AND gates each generate a pulse of one inverter delay width. The output signals of the first and second AND gates are combined using the OR gate to generate a two pulse sequence. Each pulse of the two pulse sequence has a pulse width of one inverter delay period, the two pulses are separated in time by two inverter delay periods, and the first pulse occurs when the rising-edge trigger signal is applied to the first inverter of the pattern generator string.

As would be apparent to one skilled in the art, many different configurations of logic gates may be employed for combination logic 150, such as NAND, OR, XOR, or similar gates, either alone or in combination. Also, the logic of combination logic 150 may be programmable. For such instances, certain logic elements may be enabled or disabled depending upon a control signal. By enabling or disabling selected logic elements, combination logic 150 may provide one or more predefined patterns of pulses. As shown in FIG. 1, combination logic 150 may receive an optional control signal selecting a predefined output pulse sequence of a set of pulse sequences.

In addition, to generate a given limited-length sequence of output pulses, a given implementation may be designed by defining the shape of the signal applied to pattern generator string 102 (i.e., defining a set of rising and falling edges) as well as by configuration of logic gates receiving signals from one or more taps of pattern generator string 102. The pulse width might be as short as a single inverter delay period. The shortest pulse width is desirably selected as a period at least longer than the minimum inverter delay period of the inverters in the pattern generator string. This allows for the locking state to occur, since the voltage-controlled inverters are not operating at the control signal boundary.

Reference generator string 103 and pattern generator string 102 might employ slew-rate controlled inverting amplifiers for voltage-controlled inverters 110(1) through 110(M) and inverters 111(1) through 111(N). A slew-rate controlled inverting amplifier is well known in the art, such as the slew-rate controlled inverting amplifier circuit shown in FIG. 3. As shown in FIG. 3, the inverter may be implemented with an amplifier comprising field-effect transistors (FETs) P2 and N2. The slewing rate of an amplifier is a measure of the maximum rate at which the amplifier might be driven from saturation to cutoff (i.e., the time it takes to switch the amplifier on and off, which is related to the delay through the amplifier). The slewing rate is a factor of the current through the amplifier times the gain of the amplifier, divided by the capacitance seen at the input to the amplifier. Consequently, as shown in FIG. 3, the current through the FETs P2 and N2 may be controlled using FETs P1 and N1, respectively. Thus, slew-rate controlled inverting amplifier 111(n) receives two input voltage levels: i) voltage level Vₚ at FET P1 to vary the positive-going slew rate and ii) voltage level V_{N} at FET N1 to vary the negative-going slew rate (where V_{CON} is the pair of voltages Vₚ and V_{N}). As would be apparent to one skilled in the art, other slew-rate controlled inverters circuits may be employed for the voltage-controlled inverters 110(1) through 110(1) and inverters 111(1) through 111(N).

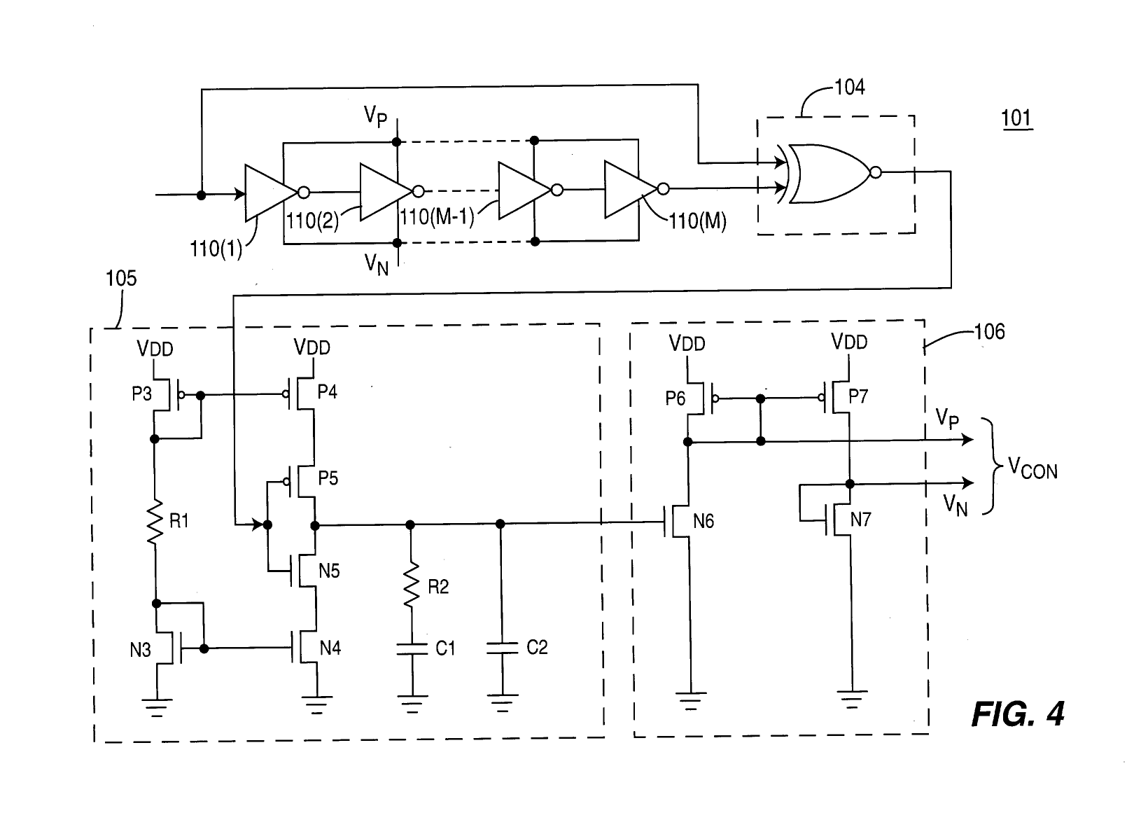

FIG. 4 shows an exemplary implementation for the delay-locked loop shown in FIG. 1, where reference generator string 103 employs slew-rate controlled inverters, such as the inverter shown in FIG. 3. Phase detector 104 is shown as an exclusive NOR (XNOR) gate having a 50% duty cycle (high and low states with equal time duration) when there is a 90-degree phase shift between the two inputs during the locked state.

Loop filter 105 is shown as a bias string comprising FETs N3 and P3 that establish gate biases for FETs N4 and P4, respectively. If matched to FETs N4 and P4, FETs N3 and P3 establish gate biases for FETs N4 and P4, respectively, such that FETs N4 and P4 have saturation currents that match each other, with the currents set by the value of resistor R1. Thus FETs N4 and P4, combined with switching transistors N5 and P5, provide a balanced charge pump for capacitor C1, “pumping up” or “pumping down” the charge stored in capacitor C1, depending on the output signal of phase detector 104. Resistor R2 is employed to adjust operation of loop filter 105, and capacitor C2 is employed to filter high frequency components from the output signal of loop filter 105. Consequently, the output voltage level of loop filter 105 is a nearly-DC voltage level that is close in value to a supply voltage Vdd when inverters 110(1) through 110(N) in reference generator string 103 are running too slow (delay is long) and need to be sped up (delay shortened). The output voltage level of loop filter 105 is a nearly-DC voltage level signal that is close in value to ground voltage when inverters 110(1) through 110(N) in reference generator string 103 are running too fast (delay is short) and need to be slowed down (delay increased).

The output voltage level of loop filter 105 is applied to control voltage generator 106. Control voltage generator 106 comprises FETs N6, P6, N7, and P7. FETs P6 and P7 are selected as the same size and matched such that FETs N6, P6, N7, and P7 operate with approximately the same current level. The width ratio of FET P6 (and FET P7) to FET N7 is desirably the same as the width ratio of FET P1 to FET N1 of FIG. 3 in the slew-rate controlled inverters (if all PMOS FETs have the same length and all NMOS FETs have the same length). As a consequence of this matching of FET width ratios, control voltages VN and VP are matched and equivalent. Matched and equivalent control voltages VN and VP causes slew-rate controlled inverters in reference generator string 103 and pattern generator string 102 to have matched positive-going and negative-going slew rates (termed “slew-rate matching”). While slew-rate matching is not necessarily employed within all embodiments of the present invention, slew-rate matching may be employed in some embodiments to provide control of the output signal S_{OUT} of pattern generator 100 when the rise and fall times of output signal S_{OUT} are equal.

One skilled in the art would recognize that additional delay error between reference generator string 103 and pattern generator string 102 may be caused by loading of the inverters of pattern generator string 102 by the logic elements of combination logic 150. Consequently, for some implementations of the present invention, logic elements coupled to inverters of the pattern generator string may be duplicated within the inverters of the reference generator string.

While the present invention has been described for a reference generator string and a pattern generator string comprising a string of coupled inverters, the present invention is not so limited. The present invention may be extended to any string of coupled delay elements in a DLL (or PLL) whose delay may be controlled via a feedback with a control signal. One skilled in the art may extend the present invention to implementations employing a DLL (or PLL) with one logic gate configuration in a locked state to generate a control voltage to control delay through elements of another logic gate configuration. For example, the reference generator string and/or pattern generator string need not be strings of inverters, but may instead be strings of flip-flops or strings of amplifiers, inverting and/or non-inverting, whose delay may be controlled by an input signal based on the locked state of the DLL.

Many applications exist that may employ a pattern generator operating in accordance with one or more exemplary embodiments of the present invention. For example, a short string of pulses forming a predefined pattern may be generated for the purposes of correlating the predefined pattern against a received signal. Such correlation is often performed for data or sequence detection. In addition, if the combination logic is programmable, the pattern generator may provide any one of a number of predefined patterns that correspond to, for example, symbols defined for user data. A transmitter may use the pattern generator to generate the symbols for transmission, while a receiver may use the pattern generator to generate the symbols for symbol detection. In addition, a short sequence of pulses exhibits a certain spectral shape. Consequently, a predefined pattern may be generated having a corresponding desired spectral shape that may be employed in wideband communications (i.e., a specific pulse pattern in the time domain has a specific, desired frequency spectrum in the frequency domain).

The present invention may be implemented as circuit-based processes, including possible implementation as a single integrated circuit, a multi-chip module, a single card, or a multi-card circuit pack. As would be apparent to one skilled in the art, various functions of circuit elements may also be implemented as processing steps in a software program. Such software may be employed in, for example, a digital signal processor, micro-controller, or general-purpose computer.

It will be further understood that various changes in the details, materials, and arrangements of the parts which have been described and illustrated in order to explain the nature of this invention may be made by those skilled in the art without departing from the principle and scope of the invention as expressed in the following claims.

What is claimed is:

1. An apparatus for generating a pulse sequence comprising:
a delay-locked loop (DLL) adapted to generate a control signal using a reference signal, the control signal employed by the DLL to adjust the delay of the reference signal passing through the DLL to a predetermined value when the DLL is in a locked state;
a pattern generator string having at least one delay element and two or more taps, wherein:
a signal input to and a signal output from a delay element of the pattern generator string appears at a corresponding tap, and
the delay of a signal passing through a delay element of the pattern generator string is based on the control signal applied to the delay element; and
a combiner adapted to combine two or more tap signals present at corresponding taps to form the pulse sequence, the two or more tap signals being present when a trigger signal is applied to the pattern generator.

2. The invention of claim 1, wherein the DLL comprises:
a reference generator string having at least one delay element, wherein the delay of a signal passing through each delay element of the reference generator string is based on the control signal applied to the delay element, and
a control signal generator adapted to generate the control signal based on a comparison of 1) the reference signal before passing through the reference string generator and 2) the reference signal after passing through the reference string generator, wherein, when the DLL is in the locked state, the control signal tends to adjust the delay of each delay element in the reference generator string to the predetermined value.

3. The invention of claim 2, wherein the control signal generator comprises:
a phase detector adapted to generate an error signal based on a phase difference between 1) the reference signal before passing through the reference string generator and 2) the reference signal after passing through the reference string generator;
a loop filter having a charge pump and adapted to filter the error signal;
a control voltage generator adapted to convert the filtered error signal from the loop filter into the control signal.

4. The invention of claim 2, wherein the reference generator string comprises a coupled string of inverters, and the pattern generator string comprises a coupled string of inverters, each inverter being a delay element.

5. The invention of claim 4, wherein each inverter is a slew-rate controlled inverter, and wherein the control signal controls the slewing rate of the slew-rate controlled inverter.

6. The invention of claim 1, wherein the combiner is a first logic gate and the trigger signal is either a rising edge or a falling edge, and wherein the first logic gate combines the signal at a first tap and a signal at a second tap to form a first pulse, a width of the first pulse based on a number of delay elements between the first tap and the second tap.

7. The invention of claim 6, wherein the first logic gate is an AND gate combining the signal at a first tap and a signal or its complement at a second tap to form a pulse.

8. The invention of claim 6, wherein the combiner comprises a second and a third logic gate, wherein the second logic gate combines the signal at a third tap and a signal at a fourth tap to form a second pulse, and the third logic gate combines the first pulse and the second pulse to form a pulse sequence.

9. The invention of claim 1, wherein the delay of a signal passing through a delay element is a delay period, and the combiner comprises one or more logic elements generating the pulse sequence such that a given pulse has a predefined pulse length of one or more delay periods and the length of time between pulses is one or more delay periods.

10. The invention of claim 1, wherein the pulse sequence is selected from a set of pulse sequences, and wherein the combiner is progammable so as to select a given one of the set of pulse sequences based on an input control signal.

11. The invention of claim 10, wherein each of set of pulse sequences corresponds to a predefined data symbol.

12. The invention of claim 1, wherein the apparatus generates the pulse sequence in a time-domain having a predefined frequency spectrum in a frequency domain.

13. The invention of claim 1, wherein the apparatus is embodied in an integrated circuit.
